(19) United States
(12) Patent Application Publication
(10) Pub. No.: US 2025/0349798 A1
(43) Pub. Date: Nov. 13, 2025

(54) MULTIPLE CHIP MODULE WITH INTEGRATED MICROCHANNEL COOLING

(71) Applicant: International Business Machines Corporation, Armonk, NY (US)

(72) Inventors: Evan Colgan, Montvale, NJ (US); Charles Leon Arvin, Poughkeepsie, NY (US); SHIDONG LI, Hopewell Junction, NY (US); Steven Paul Ostrander, Poughkeepsie, NY (US); Katsuyuki Sakuma, Fishkill, NY (US)

(21) Appl. No.: 18/659,469

(22) Filed: May 9, 2024

(51) Int. Cl. H01L 25/065; H01L 23/00; H01L 23/31; H01L 23/373; H01L 23/46; H01L 23/498; H01L 23/538

(52) U.S. Cl. CPC H01L 25/0655; H01L 23/3121; H01L 23/3731; H01L 23/46; H01L 23/49816; H01L 23/5385; H01L 24/16; H01L 24/32; H01L 24/73; H01L 2224/16227; H01L 2224/32225; H01L 2224/73253

(57) ABSTRACT

An electronic module is provided that includes a microchannel cooler having a glass manifold contacting a first side of a microchannel chip, a plurality of functional semiconductor chips located face up on a second side of the microchannel chip. Each semiconductor chip of the plurality of functional semiconductor chips is coefficient of thermal expansion (CTE) matched, and a first redistribution layer (RDL) containing structure or organic interposer is located above and in electrical contact with the plurality of functional semiconductor chips. In either case, the first RDL containing structure and the organic imposer are not CTE matched to the functional semiconductor chips.

### BACKGROUND

The present application relates to microelectronics, and more particularly to an electronic module (or electronic package) including a plurality of functional semiconductor chips that are attached to a microchannel cooler.

The microelectronic industry is continually striving to produce ever faster, smaller, and thinner electronic modules for use in various electronic products, including, but not limited to, computer server products and portable products, such as wearable microelectronic systems, portable computers, electronic tablets, cellular phones, digital cameras, and the like. Mobile products, such as cell phones, for example, often have electronic modules with small form factors which can pose many thermal challenges. Due to increasingly shrinking conductive traces, and the continually increasing complexity and power density of logic within devices, advanced cooling solutions become increasingly necessary.

Various cooling solutions have been employed, such as integrated heat spreaders, for example, which may be thermally coupled to devices residing within an electronic module, in order to dissipate heat generated from the devices. The cooling performance of a particular cooling solution may be affected by a thermal resistance between a cooling solution and electronic module, as well as by the effectiveness of heat transfer of the cooling solution. Adequate cooling of electronic module devices is necessary to prevent device failure at extended elevated temperatures, and to ensure reliable operation of the device.

### SUMMARY

An electronic module is provided that includes a microchannel cooler having a glass manifold contacting a first side of a microchannel chip, and a plurality of functional semiconductor chips located face up on a second side of the microchannel chip. Each functional semiconductor chip of the plurality of functional semiconductor chips is coefficient of thermal expansion (CTE) matched to the microchannel cooler, and a first redistribution layer (RDL) containing structure or organic interposer is located above and in electrical contact with the plurality of functional semiconductor chips. In either case, the first RDL containing structure and the organic imposer are not CTE matched to the functional semiconductor chips. Notably, there is a greater than 1 ppm/° C. CTE mismatched between the first RDL containing structure/organic imposer as compared to the functional semiconductor chips.

In one embodiment of the present application, the electronic module includes a microchannel cooler including a glass manifold contacting a first side of a microchannel chip. The electronic module further includes a plurality of functional semiconductor chips located face up on a second side of the microchannel chip, in which the second side is opposite the first side and each semiconductor chip of the plurality of functional semiconductor chips is CTE matched to the microchannel cooler. The electronic module even further includes a first RDL containing structure located above and in electrical contact with the plurality of functional semiconductor chips. In the present application, the first RDL containing structure is CTE mismatched to each of the functional semiconductor chips.

In another embodiment of the present application, the electronic module includes a microchannel cooler including a glass manifold contacting a first side of a microchannel chip. The electronic module further includes a plurality of functional semiconductor chips located face up on a second side of the microchannel chip, in which the second side is opposite the first side and each semiconductor chip of the plurality of functional semiconductor chips is CTE matched to the microchannel cooler. The electronic module even further includes an organic interposer located above and in electrical contact with the plurality of functional semiconductor chips. In this embodiment, the organic interposer is CTE mismatched to each of the functional semiconductor chips.

In either embodiment, the presence of the microchannel cooler reduces semiconductor chip operating temperature. In addition, the presence of the microchannel cooler can improve reliability and leakage currents of the functional semiconductor chips within the electronic module. The glass manifold is CTE matched to the microchannel chip and provides stiffness to the electronic module and it provides fluid distribution to the microchannel chip.

### BRIEF DESCRIPTION OF THE DRAWINGS

FIG. 1 is a cross sectional view of an exemplary structure that can be employed in the present application, the exemplary structure including a plurality of electrically conductive pillars located on a surface of a semiconductor device level.

FIG. 2 is a cross sectional view of the exemplary structure of FIG. 1 after performing a first over-molding step.

FIG. 3 is a cross sectional view of the exemplary structure of FIG. 2 after performing a planarization process.

FIG. 4 is a cross sectional view of the exemplary structure of FIG. 3 after performing a dicing process to provide a plurality of functional semiconductor chips.

FIG. 5 is a cross sectional view after bonding the functional semiconductor chips illustrated in FIG. 4 face up on microchannel cooler that includes a microchannel chip and a glass manifold.

FIG. 6 is a cross sectional view of the exemplary structure shown in FIG. 5 after performing a second over-molding step.

FIG. 7 is a cross sectional view of the exemplary structure of FIG. 6 after performing a planarization process.

FIG. 8 is a cross sectional view of the exemplary structure of FIG. 7 after revealing an upper portion of the electrically conductive pillars of each of the functional semiconductor chips.

FIG. 9A is a cross sectional view of the exemplary structure of FIG. 8 after forming a first RDL containing structure.

FIG. 9B is a cross sectional view of the exemplary structure of FIG. 8 after forming a bridge-containing structure that contains a bridge for fine pitch connections.

FIG. 10A is a cross sectional view of the exemplary structure of FIG. 9A after attaching a second RDL containing structure, and forming land grid array (LGA) pads on the second RDL containing.

FIG. 10B is a cross sectional view of the exemplary structure of FIG. 9B after attaching an organic interposer, and forming LGA pads on the organic interposer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle. Regarding the term coefficient of thermal expansion (CTE), substantial CTE matching denotes that one structure/material has a CTE that is within ±1 ppm/° C. of a CTE of another structure/material. Substantial CTE matching includes cases in which the CTE of the one structure/material is the same as the CTE of the other structure/material. In CTE mismatching, one structure/material has a CTE that is greater than ±1 ppm/° C. of a CTE of another structure/material. A difference in CTE of 1 ppm/° C. is small enough to only generate minimal thermal mismatch stresses.

Integrated circuits (ICs) generate waste heat while they operate. This heat, if not removed, can degrade the performance of the ICs. In a worst case, retained heat can lead to thermal runaway. Accordingly, it is desirable to remove waste heat from IC chips. Typically, this is done using cold plates that are attached to the chips. In a multichip assembly, a discrete cold plate can be attached to each individual chip. Alternatively, a conformable thermal interface material can be used as an intermediate layer between multiple chips and a single shared cold plate. Sometimes, a cold plate will be made flexible in order to accommodate multiple chips that may have different thicknesses or heights. Typically, cold plates are made of a metal in order to achieve high thermal conductivity.

An electronic module, or package, typically needs to provide power, input/output (I/O) connections, cooling, and mechanical protection to the active semiconductor devices which it contains. In the packaging of functional semiconductor chips, typically an organic substrate is used which fans out the fine pitch, typically 0.05 nm to 0.2 mm, controlled collapse chip connector (C4) solder bumps on the silicon die to larger pitch, typically 1.0 to 1.2 mm, BGA (ball grid array) or LGA (land grid array) connections. With a BGA, the chip package is attached to a printed circuit board (PCB) by reflowing the solder balls to form a permanent connection, whereas an LGA type interposer provides a connection where the chip package can be readily removed and replaced on the printed circuit board.

For an LGA interposer, or connector/socket, a mechanical load is required to compress springs or other contact elements to form the individual electrical connections. In general, with an organic packaging substrate, a lid formed from a thermally conductive material such as copper is attached to the chip and organic substrate to protect the chip during handling and to add mechanical strength to the organic substrate. A thermal interface material (TIM) is dispensed between the back surface of the chip and the lid to provide a thermal path. If required, a heat sink is then attached using a second TIM layer to the outside surface of the lid. The chip is mounted face, or device side, down on the packaging substrate and connected by C4s.

Typical organic laminates used for packaging chips have a coefficient of thermal expansion (CTE) of about 13 ppm/° C. to about 18 ppm/° C., which is greater than the silicon CTE, which is about 3 ppm/° C. This difference limits the size of chips which can be reliably attached to laminates with C4 solder balls, and the minimum pitch of the solder balls, due to the stresses generated during thermal cycling. The CTE mismatch between the silicon chip and the copper lid (CTE of approximately 17 ppm/° C.) means that for reliable operation of large chips, compliant and thicker TIM layers are required, which have lower performance than rigid TIM layers such as silver filled epoxy, solder, or metals such as indium.

Current generation multichip high performance compute modules incorporate stacked chips, as well as high bandwidth memory chip stacks (HBMs). Lower chips in each stack contain through silicon vias (TSVs). The chip stacks are mounted onto silicon carriers that have multiple wiring layers and TSVs for interconnecting the chips which are mounted on them. The interposers are then attached to organic laminates. A significant advantage of silicon carriers, also called interposers, is that they can be manufactured with finer pitch wiring than organic laminates and since they are CTE-matched to chips, large chips can be mounted onto them with finer pitch solder balls, both of which enable greater data bandwidth between chips. A disadvantage of silicon interposers is that they are generally thin, about 0.05 mm to 0.2 mm thick, due to the etching process used to form the TSVs, which means that they are fragile and can easily be cracked when they span a large area.

Glass which is CTE-matched to silicon can also be used to manufacture carriers or interposers with multiple fine pitch wiring layers and through vias which are in many ways functionally equivalent to silicon carriers. Both silicon and glass are brittle materials and strong in compression but fracture in tension when a critical load is exceeded. The failure strength of silicon and glass depends on the largest existing crack nucleation site. TSVs can function as crack nucleation sites. Increasingly, stacked chips are joined by “hybrid bonding” where oxide layers and copper connections are bonded directly to each other, and solder bumps are not needed. For some higher power density modules, directly integrating liquid cooling in the lid of the module is being considered to provide improved cooling. Such multichip modules as described above, are typically mounted on PCBs using LGA connections, rather than BGAs, so that they are replaceable. For the current state of the art high performance multichip modules, since materials with different CTEs are used, careful engineering, design, and assembly methods are needed to ensure long term reliable operation. It is desirable that any bending of large area silicon or glass carriers is avoided as that could potentially fracture the carrier.

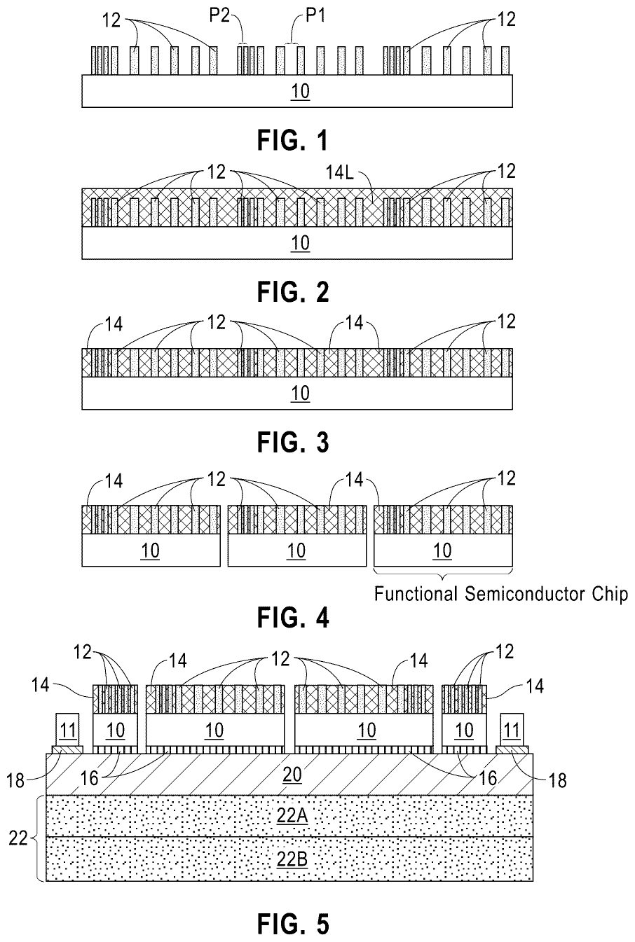

Referring first to FIG. 1, there is illustrated an exemplary structure that can be employed in the present application. The exemplary structure illustrated in FIG. 1 includes a plurality of electrically conductive pillars 12 located above a semiconductor device level 10. In the present application, the plurality of electrically conductive pillars 12 are formed on a frontside of the semiconductor device level 10. The frontside of the semiconductor device level 10 includes at least a front-end-of-the-line (FEOL) level that includes one or more semiconductor devices. In some embodiments, a middle-of-the-line (MOL) level and/or a back-end-of-the-line (BEOL) structure are formed between the semiconductor device level 10 and the plurality of electrically conductive pillars 12. In such embodiments, the MOL level and/or BEOL structure are also located on the frontside of the semiconductor device level 10.

The FEOL level of the semiconductor device level 10 includes a plurality of semiconductor devices such, as for example, transistors, capacitors, and/or resistors that are formed on surface of a semiconductor substrate. The semiconductor devices are integrated into ICs. Both the semiconductor devices and semiconductor substrate are not separately shown but are meant to be included in the region denoted as the semiconductor device level 10. The semiconductor substrate of the semiconductor device level 10 is composed of a semiconductor material having semiconducting properties. The semiconductor material can include, for example, silicon (Si), a silicon germanium (SiGe) alloy, a silicon germanium carbide (SiGeC) alloy, germanium (Ge), III/V compound semiconductors or II/VI compound semiconductors. Typically the semiconductor substrate is composed of Si. The semiconductor device level 10 can be formed utilizing any well-known FEOL process.

When present, the MOL level (not shown) includes electrically conductive contact structures that are embedded in an interlayer dielectric (ILD) material. The electrically conductive contact structures are composed of an electrically conductive metal or electrically conductive metal alloy as defined herein below for the electrically conductive pillars 12. The ILD material includes silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The MOL level can be formed utilizing any well-known MOL process.

When present, the BEOL structure includes electrically conductive wires (metal lines and/or metal vias) embedded within one or more ILD materials. The electrically conductive wires are composed of an electrically conductive metal or electrically conductive metal alloy as defined herein below for the electrically conductive pillars 12. The ILD material used in providing the BEOL structure includes one of the ILD materials mentioned above for the MOL level. The BEOL structure can be formed utilizing any well-known BEOL process.

The electrically conductive pillars 12 will be subsequently used as semiconductor chip contacts. The electrically conductive pillars 12 are composed of an electrically conductive metal or an electrically conductive metal alloy. Illustrative examples of electrically conductive metals that can be employed as the electrically conductive material of the electrically conducive pillars 12 include, but are not limited to, Cu, Ni, Al, Co, Ru, Mo, Os, Ir, or Rh. An illustrative electrically conductive alloy that can be employed as the electrically conductive material of the electrically conducive pillars 12 includes, but is not limited to, a Cu-Al alloy. In some embodiments, each electrically conductive pillar 12 that is formed on the semiconductor device level 10 is composed of a same electrically conductive material, as defined above. In one example, each electrically conductive pillar 12 is composed of Cu. In other embodiments of the present application, a first set of electrically conductive pillars 12 can be composed of a first electrically conductive material, while at least a second set of electrically conductive pillars 12 can be composed of an electronically conductive material that differs from the first electrically conductive material that provides the first set of electrically conductive pillars 12. Other variations of different sets of electrically conductive pillars having different electrically conductive materials are contemplated.

The electrically conductive pillars 12 are spaced apart from each other. In some embodiments (not shown), each electrically conductive pillar 12 is spaced apart from each other by an equal pitch. The term “pitch” is defined herein as a distance as measured from a central region of one of the electrically conductive pillars 12 to a central region of a nearest neighboring electrically conductive pillar 12. The minimum pitch is defined by the technology within the semiconductor device. For HBM, the typical pitch is 0.055 mm to 0.075 mm. For logic die, standard features range from 0.1 mm to 0.2 mm with logic die. The electrically conductive pillars 12 are used to both enable communication and power. For the large pitch technology, it is possible to have many small pitch diameter electrically conductive pillars 12 shorted together. However, this leads to limitation in power distribution and impact to signal integrity if any of the shorted pillars are damaged during thermal excursions. The diameters of the electrically conductive pillars 12 are referred as UBM (under bump metallurgy) diameters. Technologies such as GPUs have technology within the logic that enables communication with the HBMs. This requires those logic die to have regions of fine pitch and regions of large pitch technology. For those embodiments as shown in FIG. 1, a first set of electrically conductive pillars 12 is spaced apart from each other by a first pitch, P1 with a first diameter D1, while a second set of electrically conductive pillars 12 is spaced apart from each other by a second pitch, P2 with a second diameter D2 in which P2 is less than P1 and D2 is less than D1. In one example, P2 can be from 0.025 mm to 0.075 mm (fine pitch), while P1 can be from 0.10 mm to 0.20 mm (relaxed or normal pitch). The corresponding UBM, D2 for P2 can be from 0.012 mm to 0.040 mm, while the corresponding D1 for P1 can be 0.05 mm to 0.10 mm.

The plurality of electrically conductive pillars 12 can be formed utilizing techniques well-known to those skilled in the art. For example, the plurality of electrically conductive pillars 12 can be formed by depositing a blanket layer of electrically conductive metal or electrically conductive material alloy, and then patterning the as-deposited blanket layer of electrically conductive metal or electrically conductive metal alloy utilizing lithography and etching. The deposition of the blanket layer of electrically conductive metal or electrically conductive material alloy can include, for example, chemical vapor deposition (CVD), plasma enhanced chemical vapor deposition (PECVD) atomic layer deposition (ALD), physical vapor deposition (PVD) such as sputtering, plating, nano-paste sintering, transient liquid phase sintering (TLPS) or powder laser sintering. Lithography includes forming (by a deposition process) a photoresist material on a layer or structure that needs to be patterned, exposing the as-deposited photoresist material to a desired pattern of irradiation, and developing the exposed photoresist material. The etching can include a dry etching process or a chemical wet etching process. Drying etching can include, for example, reactive ion etching (RIE), laser etching, or plasma etching. Wet etching includes the use of a chemical etchant. In another embodiment, the electrically conductive pillars are formed by a plating process. In such a plating process, a conductive seed layer would be deposited, a thick photoresist layer would be patterned, the electrically conductive pillars 12 would be plated with Cu (or another of the above mentioned electrically conductive metals or metal alloys) within the resist, the photoresist layer would be stripped, and the seed layer would be etched from the field areas around the electrically conductive pillars 12.

Referring now to FIG. 2, there is illustrated the exemplary structure of FIG. 1 after performing a first over-molding step. The first over-molding step includes forming a first overburdened epoxy molding compound-containing layer 14L on top of the semiconductor device level 10, as well as between, and on top of, each of the plurality of electrically conductive pillars 12. The first overburdened epoxy molding compound-containing layer 14L is composed of cured epoxy molding compound (EMC). The term “epoxy molding compound or EMC” is used throughout the present application to denote a formulation of a thermosetting solid epoxy polymer, at least one additive, and at least one silica-based filler. The EMC can also include a curing agent and a curing catalyst. The EMC has a small filler size, excellent flow properties during molding and is mechanically stable at high-temperatures. Epoxy molding compounds generally have a CTE, below the glass transition temperature, between about 6 ppm/° C. and 30 ppm/° C. The EMC employed in the present application has a CTE of about 8 ppm/° C. The first overburdened epoxy molding compound-containing layer 14L can be formed onto the exemplary structure shown in FIG. 1 utilizing techniques well known in the art. In one example, the first overburdened epoxy molding compound-containing layer 14L can be formed by applying the EMC to the exemplary structure shown in FIG. 1 and thereafter the applied EMC is cured utilizing conditions well known to those skilled in the art such as, for example, transfer or compression molding.

Referring now to FIG. 3, there is illustrated the exemplary structure of FIG. 2 after performing a planarization process. The planarization process includes chemical mechanical planarization (CMP, also called chemical mechanical polishing) and/or grinding. The planarization process removes an upper (i.e., overburden) portion of the first overburdened epoxy molding compound-containing layer 14L that is present above each of the electrically conductive pillars 12 and reveals a topmost surface of each of the electrically conductive pillars 12. As is shown, the planarization process provides a first epoxy molding compound-containing layer 14 (i.e., a remaining portion of the first overburdened epoxy molding compound-containing layer 14L) between each of the electrically conductive pillars 12. The first epoxy molding compound-containing layer 14 has a topmost surface that is substantially coplanar with a remaining topmost surface of each of the of the electrically conductive pillars 12. It is noted that the CMP or grinding process may remove a small portion of the electrically conductive pillars 12.

Referring now to FIG. 4, there is illustrated the exemplary structure of FIG. 3 after performing a dicing process to provide a plurality of functional semiconductor chips. The dicing process (i.e., die singulation or wafer dicing) is a process in which individual semiconductor chips are separated from the exemplary structure of FIG. 3. The dicing process can include scribing and breaking, mechanical sawing (normally with a machine called a dicing saw) or laser cutting. All methods are typically automated to ensure precision and accuracy. In the present application, the functional semiconductor chips can be processor chips, memory chips, chip stacks, or any combination thereof. Each semiconductor chip includes a portion of the exemplary structure shown in FIG. 3. Notably, each semiconductor chip includes a remaining portion of the semiconductor device level 10, the electrically conductive pillars 12 and the first epoxy molding compound-containing layer 14 that is present on the remaining portion of the semiconductor device level 10. Each functional semiconductor chip that is formed after dicing has a substantially same height and is substantially CTE matched to each other. Typically, the semiconductor device level 10 is substantially thicker, about 0.8 mm, than the electrically conductive pillars 12 and the first epoxy molding compound-containing layer 14, up to 0.1 mm thick, so the composite CTE is dominated by the semiconductor device layer 10. The final composite CTE depends not only on the thickness of the layers of different materials, on their CTEs, but also on the stiffness of each material. For the case of a silicon substrate, 0.8 mm thick with a 0.1 mm thick EMC layer on top with a CTE of 8 ppm/° C. and an elastic modulus of about 20 to about 30 GPa, the composite CTE value would less than 3.5 ppm/° C., which is substantially the same CTE as a silicon chip.

Referring now to FIG. 5, there is illustrated an exemplary structure after bonding the functional semiconductor chips illustrated in FIG. 4 face up on a microchannel cooler. By “face up” it is meant that a backside of each of the functional semiconductor chips is bonded to the microchannel cooler. The presence of the microchannel cooler reduces semiconductor chip operating temperature. In addition, the use of the microchannel cooler can improve reliability and reduce leakage currents of the functional semiconductor chips within the electronic module due to the lower operating temperature. The microchannel cooler includes a microchannel chip 20 and a glass manifold 22. The glass manifold 22 provides stiffness to the electronic module and it provides fluid distribution to the microchannel chip 20 as will be discussed further herein below. The microchannel cooler can be fabricated utilizing techniques well-known to those skilled in the art. The microchannel cooler that can be employed in the present application and the fabrication technique used in forming the same are described in detail in U.S. patent application Ser. No. 18/083,554, filed Dec. 18, 2022, the entire content and disclosure of which is incorporated herein in its entirety.

The glass manifold 22 of the microchannel cooler that is employed in the present application includes one or more glass manifold layers. In an exemplary embodiment, the glass manifold 22 includes a first glass manifold layer 22A and a second glass manifold layer 22B, as shown in FIG. 5. In the present application, the first glass manifold layer 22A is bonded to the second glass manifold layer 22B, and this bonded assembly (i.e., glass manifold 22) is bonded to the microchannel chip 20. Notably, the first glass manifold layer 22A of the glass manifold 22 is bonded to the microchannel chip 20. Note that this is an exemplary embodiment and that in some embodiments the glass manifold 22 can be composed of more than two glass layers or just a single glass layer can be used.

The microchannel chip 20 includes a pattern of staggered semiconductor fins (not shown but meant to be included in the region designated as the microchannel chip 20) that can be formed by etching (e.g., RIE) into a semiconductor material. The depth of this etch can be about 300 microns. The semiconductor material that can be used as the staggered semiconductor fins of the microchannel chip 20 is substantially CTE matched to the semiconductor substrate that is present in each semiconductor chip. Typically, each staggered semiconductor fin of the microchannel chip 20 is composed of silicon. Thus, the microchannel chip 20 itself is substantially CTE matched to the functional semiconductor chips. The specific geometry and dimension of each of the semiconductor fins of the microchannel chip 20 will depend on the details of the application and can be optimized as is well-known to one skilled in the art.

The glass manifold 22 (including the first glass manifold layer 22A and the second glass manifold layer 22B) is composed of a glass material that is substantially CTE matched to the CTE of both the semiconductor substrate present in each of the functional semiconductor chips and the semiconductor material that provides the staggered semiconductor fins of the microchannel chip 20. Thus, the glass manifold 22 is substantially CTE matched to the microchannel chip 20 and each semiconductor chip. In one example, the glass material that provides the glass manifold 22 is composed of a borosilicate glass. Although not shown, cach of the first glass manifold layer 22A and the second glass manifold layer 22B contains three channels present therein and through holes which allow for a cooling liquid to flow to and from the microchannel chip 20. The three channels are spaced apart from each other, and the three channels that are present in the first glass manifold layer 22A are aligned above the three channels that are present in the second glass manifold layer 24B. The three channels within each of the first glass manifold layer 22A and the second first glass manifold layer 22B include an inlet channel located between a first outlet channel and a second outlet channel. The channels can be formed utilizing techniques well-known such as glass polishing and machining. The glass manifold layers 22A, 22B and microchannel chip 20 can be joined using a glass frit material as described in U.S. patent application Ser. No. 18/083,554.

In the present application, the functional semiconductor chips illustrated in FIG. 4 are bonded face up on the microchannel chip 20 of the microchannel cooler. Although not illustrated it is possible to also bond chip stacks face up on the microchannel cooler. Chip stacking can be performed utilizing techniques well known to those skilled in the art. As illustrated in FIG. 5, a semiconductor chip bonding interface 16 is formed between each semiconductor chip that is bonded to the microchannel chip 20 of the microchannel cooler. Bonding of the functional semiconductor chips to microchannel chip 20 of the microchannel cooler can include the use of a rigid bonding technique such as, for example, adhesive bonding, solder bonding, fusion bonding, metal-metal bonding, hybrid bonding in which a bonding dielectric material such as, for tetraethyl orthosilicate (TEOS), silicon dioxide (SiO₂), silicon carbon nitride (SiCN) and/or carbon-doped silicon oxide (SiCOH) is used, or other like rigid bonding methods with low thermal resistance. The term “low thermal resistance” is used herein to denote a unit thermal resistance of less than, or equal to, 8 C-mm²/W, or more preferably less than, or equal to, 4 C-mm²/W.

In addition to bonding the functional semiconductor chips to the microchannel chip 20 of the microchannel cooler, non-functional (or dummy) semiconductor chips 11 can also be bonded to the microchannel chip 20 to fill in any large areas and to reduce stress by replacing subsequently added EMC material with CTE matched silicon or glass. The non-functional (or dummy) semiconductor chips 11 do not include any active IC therein. The non-functional semiconductor chips 11 also do not include electrically conductive pillars 12. The non-functional semiconductor chips 11 are typically CTE matched to the microchannel cooler, and are bonded face up (i.e., the backside of the non-functional semiconductor chips 11 is bonded to the microchannel cooler). As shown in FIG. 5, a non-functional semiconductor chip bonding interface 18 is formed between each non-functional semiconductor chip 11 that is bonded to the microchannel chip 20 of the microchannel cooler. The non-functional semiconductor chips 11 can be bonded to the microchannel chip 20 of the microchannel cooler utilizing any of the rigid bonding methods mentioned above for bonding the functional semiconductor chips to microchannel chip 20 of the microchannel cooler. The non-functional semiconductor chips 11 can alternatively be fabricated from CTE matched glass and do not need to be formed from silicon.

As shown in FIG. 5, the microchannel chip 20 of the microchannel cooler has a first side to which the functional semiconductor chips and the non-functional semiconductor chips 11 are bonded thereto, and a second side, opposite the first side, to which the first glass manifold layer 22A is bonded and the second side of the microchannel chip 20 contains a microchannel and fin structures for coolant flow.

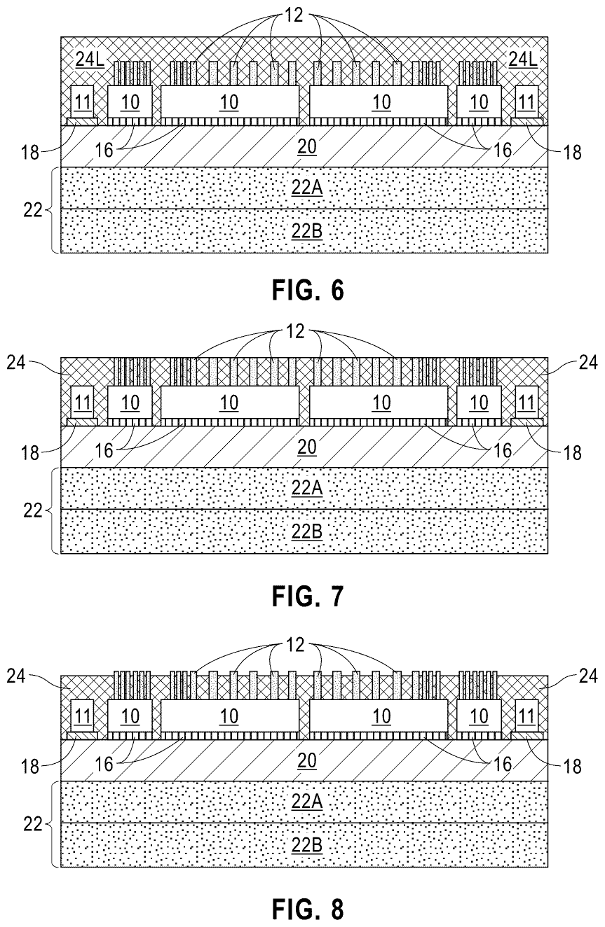

Referring now to FIG. 6, there is illustrated the exemplary structure shown in FIG. 5 after performing a second over-molding step. The second over-molding step includes forming a second overburdened epoxy molding compound-containing layer (not separately shown) adjacent to, and on top of, each of the non-functional semiconductor chips 11 and each of the functional semiconductor chips. The second overburdened epoxy molding compound-containing layer contacts the physically exposed surfaces of the first epoxy molding compound-containing layer 14 of each semiconductor chip. Collectively, the second overburdened epoxy molding compound-containing layer and the first epoxy molding compound-containing layer 14 provide a chip-encapsulating overburdened epoxy molding compound-containing layer 24L. The second overburdened epoxy molding compound-containing layer is composed of an EMC as mentioned above, and it is formed by applying the EMC and curing the EMC. The EMC that provides the second overburdened epoxy molding compound-containing layer is typically the same EMC as that used in forming the first overburdened epoxy molding compound-containing layer 14L. As an alternative to EMC, a hard silicon based dielectric material such as silicon nitride, silicon oxide, SiCOH, SiCN, or similar as described in U.S. patent application Ser. No. 18/083,554 can be used in the second over-molding step.

Referring now to FIG. 7, there is illustrated the exemplary structure of FIG. 6 after performing a planarization process. The planarization process includes CMP and/or grinding. The planarization process removes an upper portion of the chip-encapsulating overburdened epoxy molding compound-containing layer 24L and reveals a remaining topmost surface of each of the electrically conductive pillars 12. It is noted that the CMP or grinding process may remove a small portion of the electrically conductive pillars 12. As is shown, the planarization process provides a chip-encapsulating epoxy molding compound-containing layer 24 (i.e., a remaining portion of the chip-encapsulating overburdened epoxy molding compound-containing layer 24L) between each of the functional chips and non-functional chips 11 attached to the microchannel chip 20. The chip-encapsulating epoxy molding compound-containing layer 24 is located adjacent to, and on top of, each non-functional semiconductor chip 11 and adjacent to cach semiconductor chip that is bonded to the microchannel chip 20 of the microchannel cooler. The CMP or grinding process re-exposes the first epoxy molding compound-containing layer 14 on the top surface of the functional chips along with the electrically conductive pillars 12.

Referring now to FIG. 8, there is illustrated the exemplary structure of FIG. 7 after revealing an upper portion the electrically conductive pillars 12 of each of the functional semiconductor chips. The revealing of the upper portion of the electrically conductive pillars 12 of each semiconductor chip includes a recessing etching process that is selective in removing an upper portion of the chip-encapsulating epoxy molding compound-containing layers 14 and 24. In one example, the recess etching process includes a RIE. As is shown, an upper portion of the sidewall and a topmost surface of each of the electrically conductive pillars 12 is now revealed.

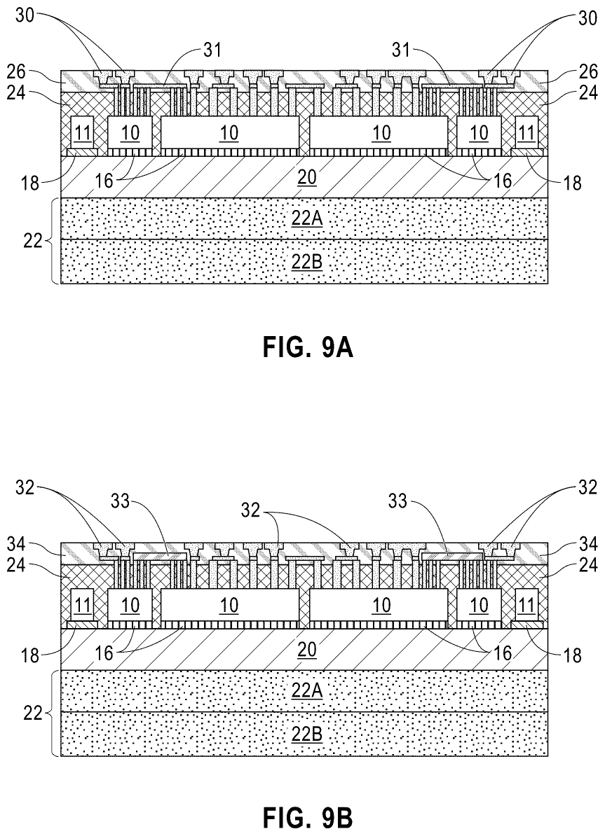

Referring now to FIG. 9A, there is illustrated the exemplary structure of FIG. 8 after forming a first RDL containing structure without any bridge. Throughout the present application, the terms “redistribution layer containing structure” or “RDL containing structure” denote a structure including metal wiring (i.e., RDL interconnects) within a polymeric substrate. The metal wiring in the RDL containing structure electrically connects one part of the electronic module to another part of the module. The metal wiring in the RDL containing structure allows for fan-out circuitry and typically lateral communication between the functional semiconductor chips. The first RDL containing structure includes first metal wiring 30 that is in electrical contact with the electrically conductive pillars 12 of a single semiconductor chip, and second metal wiring 31 that electrically connects the electrically conductive pillars 12 of two neighboring semiconductor chips together. The first metal wiring 30 can include any combination of interconnect lines and/or interconnect vias and/or metal capture pads. The second metal 31 is typically an interconnect line. The first metal wiring 30 and second metal wiring 31 include one of the electrically conductive materials (i.e., electrically conductive metals or electrically conductive metals alloys) mentioned above for the electrically conductive pillars 12. As stated above, the first metal wiring 30 and second metal wiring 31 are embedded in polymeric substrate 26 except that the metal capture pads are exposed on the top surface. For improved solderability, metal capture pads are frequently capped with Ni and Au layers. Polymeric substrate 26 is composed of one or more polymer material-containing layers. Each polymer material-containing layer that is present in the polymeric substrate 26 is composed of a polymer that has a low dielectric constant, as defined above. Illustrative examples of polymers that can be used in providing the polymeric substrate 26 include, but are not limited to, polyimide (PI), polybenzoxazole (PBO), benzocyclobutene (BCB), and fluoropolymers such as PTFE, PFA or FEP. The first RDL containing structure including metal wiring 30, 31 and polymeric substrate 26 can be formed (build) utilizing techniques well-known to those skilled in the art. The first RDL containing structure shown in FIG. 9A is typically used in embodiments in which fine pitch connections are needed. In the present application, the first RDL containing structure is not CTE matched to the functional semiconductor chips. The use of “soft” polymeric dielectrics as listed above, instead of “hard” and brittle dielectrics such as silicon dioxide, for the first RDL containing structure can help to maintain the structural integrity despite the CTE mismatch.

Referring now to FIG. 9B, there is illustrated the exemplary structure of FIG. 8 after forming a bridge-containing structure that contains bridge 33 for fine pitch connections. The bridge-containing structure includes metal wiring 32 (interconnect lines, vias, and metal capture pads) and bridge 33 that are formed in a polymeric region 34. The metal wiring 32 of the bridge-containing structure is in electrical contact with the electrically conductive pillars 12 of a single semiconductor chip, and bridge 33 electrically connects the electrically conductive pillars 12 of two neighboring semiconductor chips together. The metal wiring 32 includes one of the electrically conductive materials (i.e., electrically conductive metals or electrically conductive metals alloys) mentioned above for the electrically conductive pillars 12. The bridge 33 is composed of semiconductor material or glass CTE matched to silicon. Typically, bridge 33 is composed of silicon and contains one or more layers of fine pitch wiring and ILD material containing layers. As stated above, the metal wiring 32 and bridge 33 are embedded in polymeric region 34, except for the metal capture pads which are exposed on the top surface. The bridge-containing structure can also have through-silicon vias, in which case the electrode pads are on the top and bottom of the chip. In this case, the metal wiring 32 in the polymeric region 34 can be connected to the electrode pads on top and bottom of the bridge-containing structure. The polymeric region 34 including metal wiring 32 and the bridge 33 embedded therein can be formed utilizing techniques well-known to those skilled in the art. In one example, a damascene process can be used to form the bridge shown in FIG. 9B and a semi-additive process to form Cu lines and vias in a polyimide dielectric. In the present application, the bridge-containing structure is not CTE matched to the functional semiconductor chips.

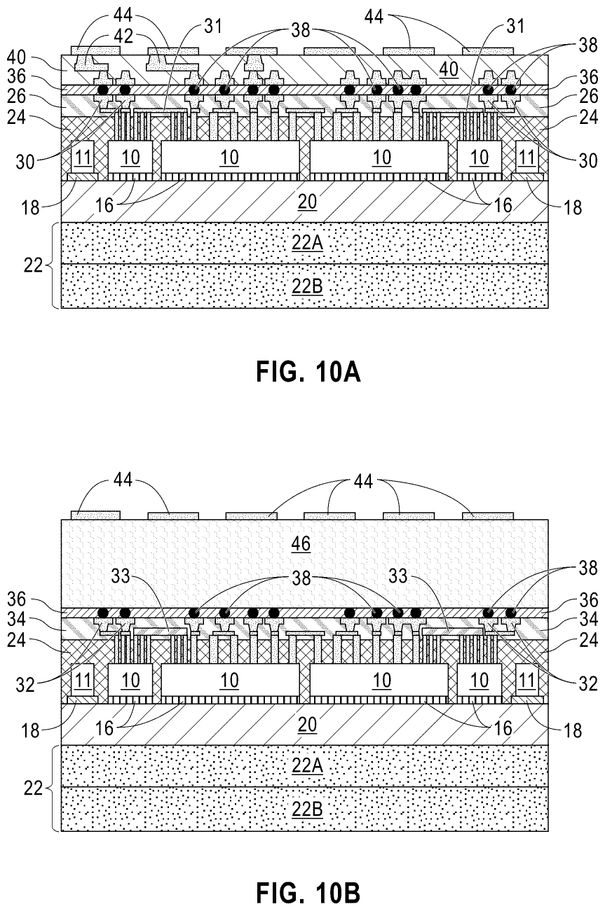

It is worth noting that it is difficult to fabricate the first RDL containing structure in FIG. 9A or the bridge-containing structure in FIG. 9B since the microchannel cooler with the attached chips results in a thicker than typical structure which is not directly compatible with silicon wafer or panel processing equipment, which is why it is desirable to separately fabricate additional wiring layers such as the second RDL containing structure in FIG. 10A or the organic interposer in FIG. 10B separately, and attach them with solder balls to the structures in FIG. 9A or FIG. 9B.

Referring now to FIG. 10A, there is illustrated the exemplary structure of FIG. 9A after attaching a second RDL containing structure formed with LGA pads 44 on the top of the second RDL containing structure. The second RDL containing structure includes third metal wiring 42 (i.e., RDL interconnects) embedded in a second polymeric substrate 40. The third metal wiring 42 (RDL interconnect lines and/or interconnect vias) is in electrical contact with the first metal wiring 30 present in the first RDL containing structure via solder balls 38 (i.e., lead-free solder or lead containing solder). The solder balls 38 are embedded in a non-conductive layer 36 that is composed of a non-conductive paste (NCP) or non-conductive polymer film (NCF). The third metal wiring 42 includes one of the electrically conductive materials (i.e., electrically conductive metals or electrically conductive metals alloys) mentioned above for the electrically conductive pillars 12. The second polymeric substrate 40 includes one or more polymer material-containing layers in which each polymer material-containing layer 26 is composed of a polymer as defined above for the first polymeric substrate 26. The second RDL containing structure is not CTE matched to the functional semiconductor chips. The use of “soft” polymeric dielectrics as listed above, instead of “hard” and brittle dielectrics such as silicon dioxide, for the second RDL containing structure helps maintain the structural integrity despite the CTE mismatch.

In this embodiment, the second RDL containing structure is formed (built upon) on a handler substrate (not shown). The second RDL containing structure that is contained on the handler substrate is then attached to the exemplary structure shown in FIG. 9A using the solder balls 38 that are embedded in the non-conductive layer 36. After attaching the second RDL containing structure, the handler substrate is removed providing the exemplary structure shown in FIG. 10A. Additional RDL containing structures can be formed as needed on top of the second RDL containing structure illustrated in FIG. 10A. In this case, smaller pitch metal capture pads would be used. Large pitch, about 1 mm, metal capture pads would only be used as LGA pads 44 on the topmost RDL containing structure.

The LGA pads 44 are composed of a metal such as, for example, Cu coated with Ni and Au, and they can be formed by deposition followed by lithographic patterning and etching, preferably as part of the topmost RDL containing structure fabrication. As is shown, some of the LGA pads 44 are in electrical contact with the third wiring 42 that is present in the second RDL containing structure. An RDL structure that is between 0.050 mm to 0.100 mm in thickness is formed at wafer level and transferred wafer-to-wafer to add additional wiring layers. This provides the thicker wiring needed for the final package without the high warpage associated with multiple RDLs on a single wafer.

Referring now to FIG. 10B, there is illustrated the exemplary structure of FIG. 9B after attached an organic interposer 46 used to enable thicker copper layers and plated through holes (PTH) for high power delivery beyond what is possible within the layers of a fine pitch RDL, formed with LGA pads 44 on top of the organic interposer 46. In this embodiment, the organic interposer 46 is attached to the exemplary structure shown in FIG. 9B by solder balls 38 that are embedded in non-conductive layer 36 that is composed of a non-conductive paste (NCP) or non-conductive polymer film (NCF). The organic interposer 46 is a layer made from an organic polymer material as described above and contains conductive wiring layers and vertical interconnects. Organic interposers are flexible, cost efficient, and provide a simple way to provide interconnectivity in the exemplary structure shown in FIG. 10B. Note that an organic interposer as described above has a structure similar to a traditional laminate substrate but with finer features and without a fiberglass core. The organic interposer is not CTE matched to the functional semiconductor chips. The LGA pads 44 are composed of a metal such as, for example, Cu coated with Ni and Au, and they can be formed by deposition followed by lithographic patterning and etching, preferably as part of the organic interposer containing structure fabrication. The use of “soft” polymeric dielectrics as listed above, instead of “hard” and stiff dielectrics such as silicon dioxide, for the organic interposer helps maintain the structural integrity despite the CTE mismatch.

In some embodiments, no second RDL containing structure or organic interposer is attached to the first RDL containing structure, but instead the metal capture pads are increased in size (not shown) to a pitch of about 1 mm and are used as LGA contact pads.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An electronic module comprising:
a microchannel cooler comprising a glass manifold contacting a first side of a microchannel chip;
a plurality of functional semiconductor chips located face up on a second side of the microchannel chip, wherein the second side is opposite the first side and each semiconductor chip of the plurality of functional semiconductor chips is coefficient of thermal expansion (CTE) matched to the microchannel cooler; and
a first redistribution layer (RDL) containing structure located above and in electrical contact with the plurality of functional semiconductor chips, wherein the first RDL containing structure is CTE mismatched to each of the functional semiconductor chips.

2. The electronic module of claim 1, wherein each semiconductor chip comprises a plurality of electrically conductive pillars and is embedded in a chip-encapsulating epoxy molding compound-containing layer.

3. The electronic module of claim 2, wherein the first RDL containing structure comprises first metal wiring in electrical contact with a single semiconductor chip of the plurality of functional semiconductor chips, and second metal wiring in electrical contact with a neighboring pair of functional semiconductor chips of the plurality of functional semiconductor chips.

4. The electronic module of claim 1, further comprising land grid array pads located above and in electrical contact with the first RDL containing structure.

5. The electronic module of claim 4, further comprising one or more additional RDL containing structures located between the land grid array pads and the first RDL containing structure, wherein the one or more additional RDL containing structures are in electrical contact with the first RDL containing structure and at least one of the land grid array pads.

6. The electronic module of claim 5, wherein the one or more additional RDL containing structures are attached to the first RDL containing structure by solder balls, and the solder balls are embedded in a non-conductive material.

7. The electronic module of claim 1, further comprising non-functional chips located face up on a second side of the microchannel chip, and spaced apart from each of the functional semiconductor chips of the plurality of functional semiconductor chips to largely fill the area not occupied by functional chips and are CTE matched to the microchannel chip.

8. The electronic module of claim 7, wherein the non-functional chips and the plurality of functional semiconductor chips are embedded in a chip-encapsulating epoxy molding compound-containing layer.

9. The electronic module of claim 1, wherein the glass manifold comprises one or more glass manifold layers and are CTE matched to the microchannel chip.

10. The electronic module of claim 1, wherein the functional chips are rigidly bonded to the microchannel cooler with a low thermal resistance.

11. An electronic module comprising:
a microchannel cooler comprising a glass manifold contacting a first side of a microchannel chip;
a plurality of functional semiconductor chips located face up on a second side of the microchannel chip, wherein the second side is opposite the first side and each semiconductor chip of the plurality of functional semiconductor chips is coefficient of thermal expansion (CTE) matched to the microchannel cooler; and
an organic interposer located above and in electrical contact with the plurality of functional semiconductor chips, wherein the organic interposer is CTE mismatched to each of the functional semiconductor chips.

12. The electronic module of claim 11, further comprising land grid array pads located above the organic interposer.

13. The electronic module of claim 11, wherein each semiconductor chip comprises a plurality of electrically conductive pillars and is embedded in a chip-encapsulating epoxy molding compound-containing layer.

14. The electronic module of claim 13, further comprising a bridge-containing structure located between the organic interposer and the electrically conductive pillars, wherein the bridge-containing structure comprises a polymeric region comprising metal wiring electrically connecting each semiconductor chip to the organic interposer.

15. The electronic module of claim 14, wherein the bridge-containing structure further comprises a bridge embedded in the polymeric region and electrically connecting a neighboring pair of functional semiconductor chips of the plurality of functional semiconductor chips to each other.

16. The electronic module of claim 14, wherein the organic interposer is attached to the bridge-containing structure by solder balls, and the solder balls are embedded in a non-conductive material.

17. The electronic module of claim 11, further comprising non-functional chips located face up on a second side of the microchannel chip, and spaced apart from each of the functional semiconductor chips of the plurality of functional semiconductor chips to largely fill the area not occupied by functional chips and are CTE matched to the microchannel chip.

18. The electronic module of claim 17, wherein the non-functional chips and the plurality of functional semiconductor chips are embedded in a chip-encapsulating epoxy molding compound-containing layer.

19. The electronic module of claim 11, wherein the glass manifold comprises one or more glass manifold layer and are CTE matched to the microchannel chip.

20. The electronic module of claim 11, wherein the functional chips are rigidly bonded to the microchannel cooler with a low thermal resistance.
